(19) United States
(12) Patent Application Publication
(10) Pub. No.: US 2015/0289316 A1
(43) Pub. Date: Oct. 8, 2015

(54) ELECTROMAGNETIC HEATING DEVICE AND ELECTROMAGNETIC HEATING METHOD

(71) Applicant: TOKYO ELECTRON LIMITED, Tokyo (JP)

(72) Inventors: Masahiro SHIMIZU, Nirasaki (JP); Yoshimasa WATANABE, Nirasaki (JP); Kentaro SHIRAGA, Nirasaki (JP)

(21) Appl. No.: 14/746,651

(22) Filed: Jun. 22, 2015

Related U.S. Application Data
(63) Continuation of application No. PCT/JP2013/082540, filed on Dec. 4, 2013.

(30) Foreign Application Priority Data
Dec. 26, 2012 (JP) 2012-282874

(51) Int. Cl. H05B 1/02; H01L 21/67; H01L 21/324; H05B 6/00; B05D 3/06

(52) U.S. Cl. CPC H05B 1/0233; H05B 6/00; B05D 3/06; H01L 21/324; H01L 21/67115

(57) ABSTRACT

An electromagnetic heating device for heating a target object by irradiating electromagnetic wave includes a chamber configured to accommodate the target object, an electromagnetic wave irradiation unit configured to irradiate the electromagnetic wave to the target object in the chamber, wherein an oscillation frequency of the irradiated electromagnetic wave is variable, and a control unit configured to control heating by the electromagnetic wave. The control unit draws, on a complex plane, complex relative permittivity characteristics indicating change in a complex relative permittivity of the target object when a frequency of the irradiated electromagnetic wave varies, also draws a non-reflection curve on the complex plane, determines a frequency of the electromagnetic wave and a thickness of the target object based on a value derived from an intersection point between the complex relative permittivity characteristics and the non-reflection curve, and performs electromagnetic heating based on the determined frequency and thickness.

This application is a Continuation Application of PCT International Application No. PCT/JP2013/082540 filed on Dec. 4, 2013, entitled “ELECTROMAGNETIC HEATING DEVICE AND ELECTROMAGNETIC HEATING METHOD,” designated the United State, which is incorporated by reference herein in its entirety for all purposes.

### FIELD OF THE INVENTION

The present invention relates to an electromagnetic heating device and method for heating an object by using electromagnetic waves.

### BACKGROUND OF THE INVENTION

Conventionally, when forming a device pattern in the manufacture of a semiconductor device or a flat panel display, a device material film is formed on a substrate and a predetermined pattern is formed on the device material film by photolithography, and then etching is performed by using the pattern as a mask.

However, the device pattern forming method using photolithography results in high cost, and therefore, it is being tried to use a film forming method using a coating printing capable of forming the device pattern with low cost per unit area.

For example, in a large device such as a solar cell, a large display and the like, it is being studied to form a device pattern on a cheap and flexible plastic substrate. However, in this technique, it is highly required to lower the cost per unit area. Therefore, it is strongly required to use the coating printing for the formation of the device pattern. Such a technique of forming a wiring or an electrode on the plastic substrate by the coating printing is being applied to an organic TFT (thin film transistor) and the like.

Meanwhile, a technique of forming a film by using the coating printing is being applied to a technique of forming pixels on a glass substrate as well as the plastic substrate, e.g., to an organic EL (electroluminescence).

In a case of performing the coating printing of a device on a plastic substrate, a coating film is formed by applying a coating ink containing a device material added with a solvent and the like. Then, the coating film is heated to remove the solvent and the like and modified to form a device pattern having a desired characteristics.

As a heating method of the coating film, a resistance heating is general. However, in the resistance heating, in order to efficiently and perfectly remove the solvent and the like, it is necessary to heat the coating film to a temperature above the heat-resistant temperature of the plastic substrate, and long-time heating is also needed.

In a case of forming pixels of the organic EL on the glass substrate, a vacuum dry technique is used. However, in the vacuum dry technique, a pixel shape becomes a concave shape after dry, so that yield rate of the organic EL characteristics is poor.

For this reason, electromagnetic heating is attracting attention, which is capable of removing the solvent and the like by selectively heating the coating film, almost without heating the substrate in the case of the plastic substrate and while maintaining the pixel in good shape in the case of the organic EL (see, e.g., PCT Patent Publication No. WO2012/115165).

In manufacturing processes of the semiconductor device, there is a process of forming an impurity diffusion layer by performing an impurity activation annealing after injecting impurities to a semiconductor substrate. Conventionally, in an impurity activation process or an activation and crystallization process, a heating process for a short time at a high temperature of 1000° C. or more by a spike annealing using a halogen lamp is performed. Recently, however, along with the miniaturization of a design rule of the semiconductor device, an extremely thin diffusion layer (ultra shallow junction (USJ)) is required, so that an annealing technique at a low temperature in which thermal diffusion of impurities is suppressed is required. As a technique for suppressing impurity diffusion, it is being studied a solid phase epitaxy (SPE) in which an impurity doping region becomes amorphous; the region is doped with impurity; and then annealing is performed at a low temperature, thereby performing recrystallization and impurity activation. As a heating method capable of performing annealing in a low temperature, electromagnetic heating has been suggested (see, e.g., Japanese Patent Application Publication No. 2009-516375).

Although the electromagnetic heating has been attracting attention as a new heating method for drying or modification, it is difficult to make an object absorb the electromagnetic wave always efficiently to obtain desired characteristics.

### SUMMARY OF THE INVENTION

In view of the above, the present invention provides an electromagnetic heating device and method which can make electromagnetic wave be efficiently absorbed onto a heating target object.

In accordance with an aspect of the present invention, there is provided an electromagnetic heating device for heating a target object by irradiating electromagnetic wave, the electromagnetic heating device including: a chamber configured to accommodate the target object; an electromagnetic wave irradiation unit configured to irradiate the electromagnetic wave to the target object in the chamber, wherein an oscillation frequency of the irradiated electromagnetic wave is variable; and a control unit configured to control heating by the electromagnetic wave, wherein the control unit draws, on a complex plane, complex relative permittivity characteristics indicating change in a complex relative permittivity of the target object when a frequency of the irradiated electromagnetic wave varies, also draws a non-reflection curve on the complex plane, determines a frequency of the electromagnetic wave and a thickness of the target object based on a value derived from an intersection point between the complex relative permittivity characteristics and the non-reflection curve, and performs electromagnetic heating based on the determined frequency and thickness.

In the electromagnetic heating device, the control unit may calculate a wavelength λ by inserting a value of the thickness d of the target object into a thickness/wavelength ratio (d/λ) derived from the non-reflection curve at the intersection point, and obtain a frequency f of the electromagnetic wave from the wavelength λ. In this case, the control unit may previously store data of the complex relative permittivity characteristics indicating a change in the complex relative permittivity of the target object drawn on the complex plane when the frequency of the irradiated electromagnetic wave varies, and data of the non-reflection curve drawn on the complex plane.

The electromagnetic heating device may further include an electromagnetic wave intensity meter configured to measure intensity of the electromagnetic wave irradiated from the electromagnetic wave irradiation unit, wherein the control unit may set a central value of the obtained frequency to the frequency f, and correct a frequency of the electromagnetic wave irradiated from the electromagnetic wave irradiation unit to become a frequency at which reflection intensity measured by the electromagnetic wave intensity meter becomes a minimum while changing the frequency of the electromagnetic wave from the frequency f that is the central value.

The electromagnetic heating device may further include a thermometer configured to measure a temperature of the target object, wherein the control unit may set a central value of the obtained frequency to the frequency f, and correct a frequency of the electromagnetic wave irradiated from the electromagnetic wave irradiation unit to become a frequency at which a measuring temperature value of the target object by the thermometer is equal to a setting temperature value while changing the frequency of the electromagnetic wave from the frequency f that is the central value.

The electromagnetic heating device may further include a gas concentration meter configured to measure gas concentration of a predetermined gas in the process chamber, wherein the control unit may set a central value of the obtained frequency to the frequency f, and correct a frequency of the electromagnetic wave irradiated from the electromagnetic wave irradiation unit to become a frequency at which a measuring value of concentration of a predetermined gas detected by the gas concentration meter is equal to a setting value of the concentration while changing the frequency of the electromagnetic wave from the frequency f that is the central value.

Further, in the electromagnetic heating device, the control unit may obtain a frequency from the complex relative permittivity characteristics at the intersection point and obtain a thickness of the target object from the obtained frequency and a thickness/wavelength ratio (d/λ) derived from the non-reflection curve at the intersection point.

A variable range of the oscillation frequency of the electromagnetic wave irradiation unit may be a part of a range between 0.1 kHz and 10 THz.

In accordance with another aspect of the present invention, there is provided an electromagnetic heating method for heating a target object by irradiating electromagnetic wave, the electromagnetic heating method including: drawing, on a complex plane, complex relative permittivity characteristics indicating a change in complex relative permittivity of the target object when a frequency of irradiated electromagnetic wave varies; drawing a non-reflection curve on the complex plane; determining a frequency of the electromagnetic wave and a thickness of the target object based on a value derived from an intersection point between the complex relative permittivity characteristics and the non-reflection curve; and performing electromagnetic heating based on the determined frequency and thickness.

In the electromagnetic heating method, a wavelength λ may be calculated by inserting a value of the thickness d of the target object into a thickness/wavelength ratio (d/λ) derived from the non-reflection curve at the intersection point, and a frequency f of the electromagnetic wave may be obtained from the wavelength λ.

Further, a frequency may be obtained from the complex relative permittivity characteristics at the intersection point and a thickness of the target object may be obtained from the obtained frequency and a thickness/wavelength ratio (d/λ) derived from the non-reflection curve at the intersection point.

In the present invention, the electromagnetic heating may be used for drying or modification of a coating film formed on a substrate. Further, the electromagnetic heating may be used in annealing for impurity activation or for impurity activation and recrystallization after introducing impurities to a substrate for forming a semiconductor substrate.

In accordance with the present invention, electromagnetic waves are irradiated based on an electromagnetic wave absorption design using a complex relative permittivity characteristics indicating change in a complex relative permittivity of the target object when a frequency of the irradiated electromagnetic wave varies, and a non-reflection curve. Therefore, both of electromagnetic wave penetration into the target object from the outside and electromagnetic wave absorption in the target object are considered, and thus the whole electromagnetic wave energy is theoretically absorbed into the target object. Accordingly, electromagnetic waves can be efficiently absorbed into the target object.

### BRIEF DESCRIPTION OF THE DRAWINGS

FIG. 1A is a view showing a model of a case where electromagnetic wave is perpendicularly incident to an electromagnetic wave absorber of a single layer type;

FIG. 1B is a view showing an equivalent circuit of the model shown in FIG. 1A;

FIG. 2 is a view showing a non-reflection curve in a complex plane;

FIG. 3 is a view showing an intersection point between a curve indicating characteristics of a complex relative permittivity and the non-reflection curve in the complex plane;

FIG. 4A is a view showing the non-reflection curve and ∈′∈″ characteristics of Ag nanoparticle ink (AgNPI-R);

FIG. 4B is an enlarged view of a part of the non-reflection curve and the ∈′∈″ characteristics shown in FIG. 4A;

FIG. 5 is a view showing the non-reflection curve and the ∈′∈″ characteristics of air and plastic substrate;

FIG. 6A is a view showing the non-reflection curve and the ∈′∈″ characteristics of Si substrate doped with impurities;

FIG. 6B is an enlarged view of a part of the non-reflection curve and the ∈′∈″ characteristics shown in FIG. 6A; FIG. 7 is a view showing the non-reflection curve and the ∈′∈″ characteristics of insulating materials such as SiO₂ and the like;

FIG. 8A shows a TEM picture of a cross section after irradiating electromagnetic wave to a Si substrate doped with impurities for 5 minutes;

FIG. 8B shows a TEM picture of a cross section after irradiating electromagnetic wave to the Si substrate doped with impurities for 30 minutes;

FIG. 9 is a view showing a change in B concentration in a depth direction after irradiating electromagnetic wave to the Si substrate doped with impurities for 5 minutes and 30 minutes;

FIG. 10 is a cross-sectional view showing a schematic configuration of a first example of an electromagnetic heating device that can implement an electromagnetic heating method in accordance with an embodiment of the present invention;

FIG. 11 is a cross-sectional view showing a schematic configuration of a second example of the electromagnetic heating device that can implement the electromagnetic heating method in accordance with the embodiment of the present invention;

FIG. 12 is a cross-sectional view showing a schematic configuration of a third example of the electromagnetic heating device that can implement the electromagnetic heating method in accordance with the embodiment of the present invention;

FIG. 13 is a cross-sectional view showing a schematic configuration of a fourth example of the electromagnetic heating device that can implement the electromagnetic heating method in accordance with the embodiment of the present invention; and

FIG. 14 is a cross-sectional view showing a schematic configuration of a fifth example of the electromagnetic heating device that can implement the electromagnetic heating method in accordance with the embodiment of the present invention.

### DETAILED DESCRIPTION OF THE EMBODIMENTS

Hereinafter, embodiments of the present invention will be described.

As shown in the following equation (1), electromagnetic heating is represented as a sum of conduction loss (induction loss), dielectric loss and magnetic loss.

P=½×πfσ|E|²+πf∈₀∈″ᵣ|E|₂+πfμ₀μ″ᵣ|H|², (1)

where p is energy loss per unit volume (W/m³), E is electric field (V/m), H is magnetic field (A/m), σ is electric conductivity (S/m), f is frequency (s⁻¹), ∈₀: vacuum permittivity (F/m), ∈″ᵣ is imaginary part of complex permittivity, μ₀ is permeability of vacuum (H/m), μ″ᵣ is imaginary part of complex permeability.

In the electromagnetic heating, selective heating is possible by using differences of induced loss, dielectric loss and magnetic loss depending on types of material. The imaginary part of complex permittivity expresses such absorption characteristics.

In a case of heating a target object by irradiating electromagnetic waves, it is required to plan an electromagnetic wave absorption design so as to make the target object absorb electromagnetic waves from the outside toward the inside. If the electromagnetic waves and a property of the target object satisfy a non-reflection condition of a wave propagation equation, the electromagnetic wave energy is totally absorbed into the object in theory.

In the present embodiment, the electromagnetic heating is performed by using the electromagnetic wave absorption design. By doing so, an optimal frequency of electromagnetic wave can be selected depending on the thickness of the target object, thereby allowing the target object to efficiently absorb the electromagnetic waves and to be selectively heated.

In the electromagnetic wave absorption design, first, in the cases of varying a frequency of irradiated electromagnetic wave, a complex relative permittivity of the target object is plotted in a complex plane, in which the vertical axis is set to the imaginary part of the complex relative permittivity and the horizontal axis is set to the real part of the complex relative permittivity, to show the characteristics of the complex relative permittivity (∈′∈″ characteristics). This is called ColeCole-plot or Nyquist-plot, which is an analysis method used in an electrochemical impedance method.

By using the electrochemical impedance method, characteristics of an equivalent circuit for matching the capacity component with resistance component, and characteristics of two time constants, negative resistance and the like can be found from the complex plane plot of the complex relative permittivity of, e.g., Ag nano particle ink used in the printing.

Next, a non-reflection curve is drawn in the complex plane. The non-reflection curve is depicted based on a non-reflection conditional expression in which reflection coefficient becomes 0. The non-reflection conditional expression is solved by a Newton-Raphson method.

An analysis of an electromagnetic wave absorber is performed based on a transmission line theory. In this theory, the interpretation is performed under an assumption that incident wave is plane wave and an absorber is a far field that is flat and infinitely large (about 10λ when compared to a wavelength λ)

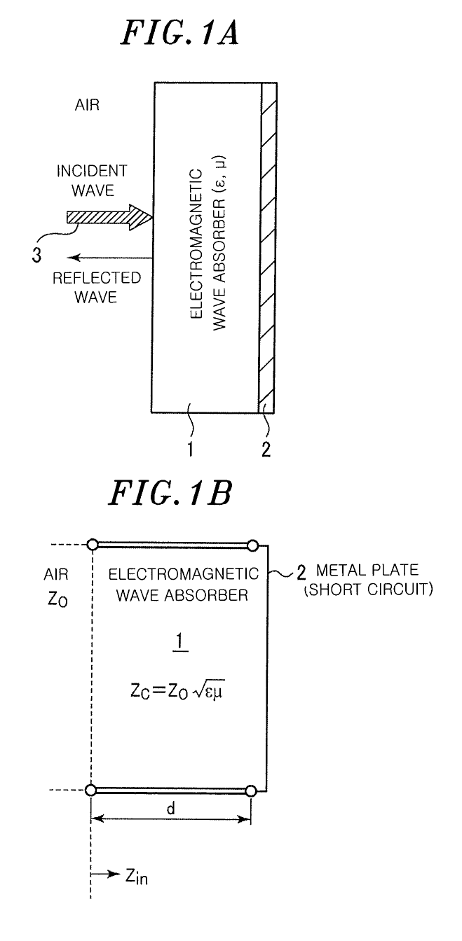

Now, a case is considered where electromagnetic waves are incident perpendicularly to an electromagnetic wave absorber of a single layer type shown in FIG. 1A. In FIG. 1A, a metal plate 2 is provided at a rear side of the absorber 1 having a thickness d, and electromagnetic wave (plane wave) 3 is irradiated. Under the above assumption, if the absorber 1 is substituted with a transmission line, an equivalent circuit shown in FIG. 1B is obtained. Here, if a wave impedance in free space of the plane wave is Z₀, an input impedance to the receiving edge from a point at distance d away from a receiving edge is Zᵢₙ, and a reflection coefficient is S, a matching condition of the non-reflection condition becomes the following equation (2).

S=(Zᵢₙ−Z₀)/(Zᵢₙ+Z₀)=0 (2)

That is, the following equation (3) is established.

Z₀=Zᵢₙ (3)

Then, the non-reflection curve is the same as the equation (4) below.

Zᵢₙ/Z₀=1 (4)

Further, the following equation (5) is obtained.

Zᵢₙ=Z₀√(μ/∈)×tan h(j×2πd/λ×√(∈μ)), (5)

where μ is a complex relative permeability, ∈ is a complex relative permittivity, d is a thickness, and λ is a wavelength of electromagnetic wave.

From the equations (4) and (5), the following equation (6) is obtained.

1=√(μ/∈)×tan h(j×2πd/λ×√(∈μ)) (6)

Impedance of the electromagnetic wave absorber Z_{c} is represented as Z_{c}=Z₀×√(∈μ). In a case of a dielectric substance, μ≈1, ∈=∈′−j∈″. Therefore, the equation (6) can be expressed as the equation (7).

1=(1/√∈)×tan h(j×2πd/λ×√∈) (7)

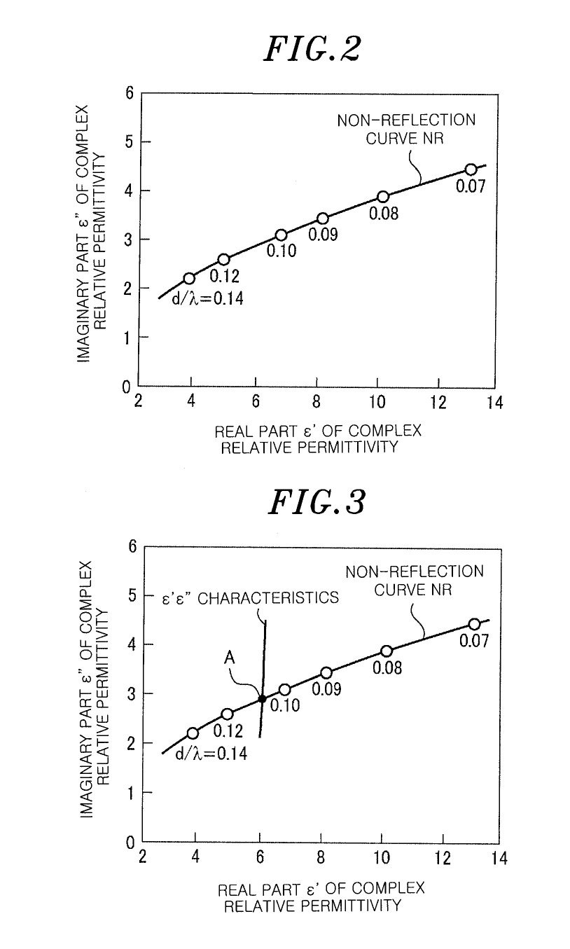

In the equation (7), by using a thickness d/λ of the absorber standardized by the wavelength λ as a parameter, values of the real part ∈′ and imaginary part ∈″ of the complex relative permittivity are found. By drawing the values (theoretical value) on the complex plane (∈′−∈″ plane), a non-reflection curve NR is obtained. An example of the non-reflection curve NR is shown in FIG. 2.

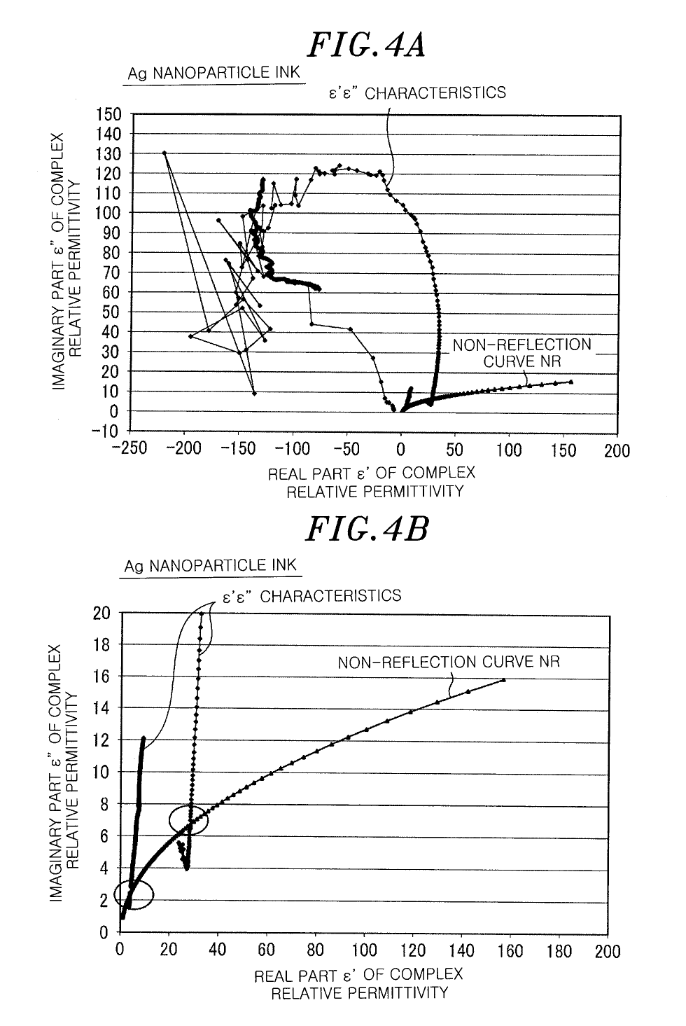

As shown in FIG. 3, the complex relative permittivity of the above-mentioned electromagnetic wave absorber is actually measured with respect to the frequency of the irradiated electromagnetic wave, the non-reflection curve NR of the electromagnetic wave absorber is depicted on the complex plane in which a curve indicating an aspect of the changes of the complex relative permittivity (complex relative permittivity characteristics/∈′∈″ characteristics) is drawn, and the electromagnetic wave absorber is realized at a point at which a curve of the ∈′∈″ characteristics intersects with the non-reflection curve (intersection point, a point A in FIG. 3).

In other words, electromagnetic waves are irradiated based on a frequency value of the ∈′∈″ characteristics and d/λ value of the non-reflection curve at the intersection point, thereby realizing highly efficient electromagnetic heating depending on a thickness of the target object. By using such an electromagnetic wave absorption design, both of electromagnetic wave penetration into the target object from the outside and electromagnetic wave absorption in the target object are considered, and thus the whole electromagnetic wave energy is theoretically absorbed into the target object. Therefore, electromagnetic waves are efficiently absorbed into the target object.

Specifically, in a case where the thickness of the target object can vary while the frequency of the electromagnetic wave is fixed, a frequency f is obtained from the ∈′∈″ characteristics at the intersection point, and a thickness d is obtained from the frequency f and the d/λ value of the non-reflection curve at the intersection point. On the other hand, in a case where the frequency of the electromagnetic wave can vary while the thickness of the target object is fixed, a d/λ value is obtained from the non-reflection curve at the intersection point, a wavelength λ is calculated by inserting a real value of the thickness d of the target object into the d/λ value, and an actual frequency f is obtained from the wavelength λ. By doing so, the frequency of electromagnetic wave and the thickness of the target object are determined, so that the electromagnetic heating satisfying the electromagnetic wave absorption design can be realized

The above example shows a case of using a dielectric as the electromagnetic wave absorber. However, even in a case of using a conductor or semiconductor as the electromagnetic wave absorber, the non-reflection curve can be obtained by solving the non-reflection conditional expression.

PCT Patent Publication No. WO2012/115165 discloses that dielectric dispersion of a coating film as a target object to be heated is measured, absorptivity corresponding to a frequency of the electromagnetic wave is obtained, and electromagnetic waves of a frequency band corresponding to a peak of the imaginary part of the complex relative permittivity are irradiated to the coating film, thereby selectively heating the coating film. However, in this method, electromagnetic wave absorption in the target object is only considered, and a condition for absorbing electromagnetic waves from the outside into the target object is not considered. Accordingly, efficient electromagnetic heating cannot always be performed. On the contrary, in the present embodiment, as described above, both of electromagnetic wave penetration into the target object from the outside and electromagnetic wave absorption in the target object are considered by using the electromagnetic wave absorption design, and thus efficient electromagnetic heating becomes possible.

For example, although not shown in the drawing, ∈′∈″ characteristics of water and non-reflection curve NR have two intersection points, and a frequency/thickness is a combination of 275 kHz/2.9 m and 3.3 GHz/2.6 mm. An absorption frequency is determined by the electromagnetic wave absorption design and an optimal thickness of the target object is determined corresponding to the absorption frequency. In this result, 2.45 GHz of a microwave oven is close to a frequency (3.3 GHz) of moisture drying.

(Application to Coating Printing)

Next, an example in which an electromagnetic heating method of the present embodiment is applied to the coating printing will be described.

The coating printing technique (printed electronics) is being considered as a technique for cheaply forming device patterns. In this example, the electromagnetic heating of the present embodiment is used in the coating printing.

In a large device such as a solar cell, a large display and the like, when forming a device such as an organic TFT (thin film transistor) and the like by forming wires/electrodes on a cheap and flexible plastic substrate, a coating film coated by a coating composition including a film component serving as the wires/electrodes is formed on the plastic substrate, and then the aforementioned electromagnetic heating is performed onto the coating film. The agglomeration of metal nanoparticles and the removal of dispersant and the like are facilitated by applying the electromagnetic heating to the drying and baking (modification) of an ink and the like constituting the coating film, so that reduction of resistivity is quickened. For this reason, speed of the drying and baking of the coating film can be increased.

Further, in an organic EL (electroluminescence), a glass substrate is coated with an ink or the like that is a coating composition including a component for forming pixels to form a coating film, and the aforementioned electromagnetic heating is performed onto the coating film. In a case of using a conventional vacuum drying which has no temperature variation in order to dry an ink or the like constituting the coating film for forming pixels, the influence of surface tension of the ink becomes great due to the microscale, so that concentration difference Marangoni convection is generated and thus the pixels become to have a concave shape. On the contrary, in a case of using the electromagnetic heating, temperature variation is generated in the ink, so that heat convection (Bernard convention or temperature difference Marangoni convection) is generated. The heat convection flows in the opposite direction to a convection causing the pixels to have a concave shape. Accordingly, since it is suppressed that the pixels become to have a concave shape, the shapes of the pixels can be planarized and thus uniformity can be improved.

As for the substrate, a plastic substrate or a glass substrate may be used depending on the purpose. In a case of using a plastic substrate, a cheap PET (Polyethylene terephthalate), PEN (Polyethylene naphthalate), PC (Polycarbonate), PI (Polyimide) or the like can be used suitably.

As the film component, when the film is a conductive film such as a wiring or an electrode, one including, e.g., metal nanoparticles is used; when the film is a semiconductor film, one including, e.g., an organic semiconductor material is used; when the film is dielectric film, one including an organic dielectric material is used; and in a case where the film becomes pixels of an organic EL, one including a luminescent organic material and the like is used. The coating composition may be made coatable by appropriately mixing the film component with a solvent, a polymer, a dispersant, a binder, various additives and the like depending on a material of the film component and a coating method to adjust the viscosity. Typically, a coating ink is used.

The metal nanoparticles are formed of minute metal particles having a particle diameter of about 1 to several hundred nm. As a metal constituting the metal nanoparticles, a metal applicable to fine metal wirings is used. Typically, any one of Ag, Cu and Al or an alloy including any one of those is used. In this case, the coating composition can be obtained by dispersing the metal nanoparticles into an appropriate solvent.

As for the organic semiconductor material, there are a polycyclic aromatic hydrocarbon such as pentacene, anthracene, rubrene, and the like, a low molecular weight compound such as tetracyanoquinodimethane (TCNQ) and the like, and a polymer such as polyacetylene, poly-3-hexylthiophene (P3HT), polypphenylenevinylene (PPV), alkyl benzothieno benzothiophene (Cu-BTBT) and the like. The coating composition using the organic semiconductor material includes, e.g., a P3HT solution using chloroform (CHCl₃) as a solvent.

As for the organic dielectric material, there are polyvinylphenol (PVP) and cyanoethylpullulan (CyEPL) and the like. The coating composition using the organic dielectric material includes, e.g., a PVP solution.

As for the luminescent material of the organic EL, there may be used a material that uses as a solute a fluorescent material, a phosphorescent material or a delayed fluorescent material and uses as a solvent a halogenated organic compound, a aromatic hydrocarbon, an ether, an ester, an alcohol, a keton, a sulfoxide, an amide, water or the like.

As the coating method for applying the coating composition, it is preferable to employ a method that has a good conformability to fine patterns. For example, inkjet printing, screen printing, microcontact printing (MCP) and the like may be appropriately used. In addition, a spin coat method, a bar coat method, a reversal printing method may be used.

In a state where a substrate is coated with the coating composition, components such as a solvent, dispersant and the like are contained in the coating film. In a case of using the metal nanoparticles, the metal nanoparticles are not sufficiently agglomerated and cannot approach a structure of bulk metal, so that electric conductivity is low. Also in a case of using the organic semiconductor material or the organic dielectric material, it is difficult to obtain initial characteristics due to a reason that components such as a solvent, dispersant and the like are contained in the coating film and a reason that the organic semiconductor material or the organic dielectric material does not form a desired structure. On this account, the electromagnetic heating in accordance with the present embodiment is performed by irradiating electromagnetic waves onto the coating film formed by applying the coating composition. From this, drying or modification of the coating film or both of the drying and the modification are performed to form a film having a desired conductivity, semiconductor characteristics, or dielectric characteristics. The electromagnetic waves may be irradiated to at least the coating film constituting coating patterns, but typically, are irradiated to the entire surface of a substrate.

If electromagnetic waves are irradiated, the coating composition is directly heated by absorbing the electromagnetic waves to accelerate physical chemistry action in the coating film in a solution state, for example. By this, decomposition of the solvent or modification of the coating composition is performed, so that a desired film is formed. At this time, if the substrate is a plastic substrate, the substrate is hardly heated since electromagnetic waves penetrate the plastic. Further, if the coating composition is pixels of organic EL, the coating film can be dried in a flat and uniform shape by irradiating electromagnetic waves.

As described above, the electromagnetic heating that uses the electromagnetic wave absorption design in accordance with the present embodiment is performed onto the coating film printed by coating. Accordingly, efficient heating can be carried out.

Next, a test example of a case where Ag nanoparticle ink is used as the coating composition will be described.

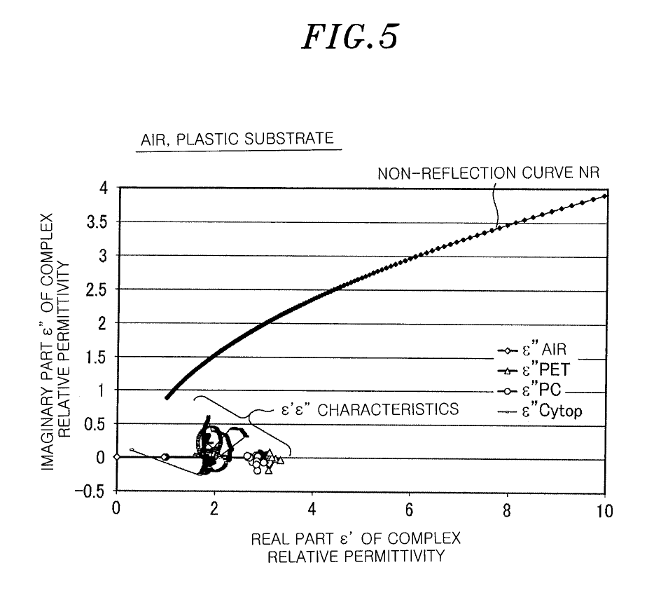

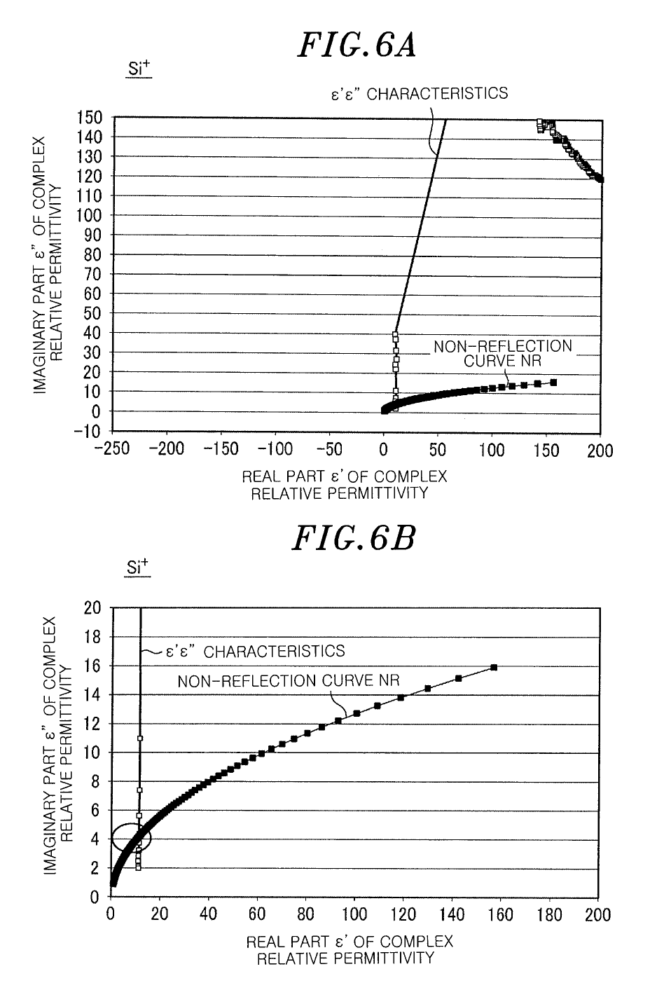

FIG. 4A illustrates, when a frequency of the electromagnetic wave irradiated to the Ag nanoparticle ink (AgNPI-R) varies between 100 kHz and 100 GHz, ∈′∈″ characteristics indicating the change of the complex relative permittivity and non-reflection curve. FIG. 4B is an enlarged view of a part of FIG. 4A. As shown in FIGS. 4A and 4B, there is an intersection point between the ∈′∈″ characteristics (experimental value) and the non-reflection curve (theoretical value). By reading the intersection point, a frequency of the electromagnetic wave and a thickness of the target object to be heated can be derived. In this regard, as shown in FIG. 5, it is known that in a case of air and plastic (PET, PC and amorphous fluororesin (Cytop™)) constituting a substrate, there is no intersection point between the ∈′∈″ characteristics (experimental value) and the non-reflection curve (theoretical value), and selective heating of the Ag nanoparticle ink is possible.

Based on the values read from FIGS. 4A and 4B, the electromagnetic wave absorption design was performed with respect to AgNPI-R and another Ag nanoparticle ink (AgNPI-J). The results are shown in the following Table 1.

TABLE 1

| | From complex relative | | | From non- | | | | |
|---|---|---|---|---|---|---|---|---|
| | permittivity | | | reflection curve | | | | Note |
| | (Experiment) | | | (Theory) | | | | (Absorption |
| Material | ε′ | ε″ | f | ε′ | ε″ | d/λ | d (m) | amount) |
| AgNPI-R | 4.09 | 2.41 | 51 GHz | 4.28 | 2.46 | 0.127 | 7.5 * 10⁻⁴ | Intersection |
| | | | | | | | | point exists |
| | | | | | | | | (99.9999%) |
| AgNPI-J | 8.68 | 7.48 | 40 GHz | 7.95 | 3.46 | 0.091 | 6.8 * 10⁻⁴ | Intersection |
| | | | | | | | | point exists |

From Table 1, it is found that when a frequency of the irradiated electromagnetic wave is between 40 GHz and 51 GHz, a thickness of 680 to 750 μm becomes a design value of the non-reflection condition.

Referring to the above electromagnetic wave absorption design as a guideline, a test was performed with the electromagnetic wave of 28 GHz frequency. Here, wirings were formed on a substrate made of SiO₂, PC (polycarbonate) and PC/Cu (polycarbonate whose backside is coated with a copper foil) by using the Ag nanoparticle ink (AgNPI-R, -J) and Ag nano paste (AgNPP), and then, electromagnetic waves were irradiated to the wirings in the atmosphere for 5 minutes. The result is shown in Table 2.

TABLE 2

| | | | | | | Sheet | | |
|---|---|---|---|---|---|---|---|---|
| | | Ink liquid | | Substrate | | resistance | Film | |
| | Ink | thickness | Substrate | Temp. | | value | thickness | resistivity |
| No. | type | dₒ (cm)* | type | Tₘₐₓ (° C.) | | (Ω/□) | d₁ (cm) | ρ (Ωcm) |
| 1 | AgNPI-R | 7.50 × 10⁻² | SiO₂ | 348 | 401 | 8.47 × 10⁻² | 1.00 × 10⁻⁴ | 8.47 × 10⁻⁶ |
| 2 | | 1.00 × 10⁻² | | 154 | 198 | 5.22 × 10⁻² | 1.00 × 10⁻⁴ | 5.22 × 10⁻⁶ |
| 3 | | 8.00 × 10⁻⁴ | | 195 | 141 | 6.59 × 10⁻² | 1.00 × 10⁻⁴ | 6.59 × 10⁻⁶ |
| 4 | AgNPI-J | 7.50 × 10⁻² | PC | 64 | 211 | 3.94 × 10⁻³ | 5.00 × 10⁻⁴ | 1.97 × 10⁻⁶ |
| 5 | | 1.00 × 10⁻² | | 123 | 113 | 3.44 × 10⁻³ | 4.00 × 10⁻³ | 1.38 × 10⁻⁵ |
| 6 | | 8.00 × 10⁻⁴ | | 95 | 107 | 5.44 × 10⁻³ | 4.00 × 10⁻³ | 2.18 × 10⁻⁵ |
| 7 | AgNPI-J | 7.50 × 10⁻² | PC/Cu | 121 | 184 | 2.72 × 10⁻³ | 2.50 × 10⁻³ | 6.80 × 10⁻⁶ |
| 8 | | 1.00 × 10⁻² | | 198 | 142 | 2.27 × 10⁻² | 1.00 × 10⁻³ | 2.27 × 10⁻⁵ |
| 9 | | 8.00 × 10⁻⁴ | | 122 | 111 | 3.76 × 10⁴ | 5.00 × 10⁻³ | 1.88 × 10⁻² |
| 10 | AgNPP | 1.50 × 10⁻² | PC | 122 | 92 | 7.89 × 10⁻³ | 5.50 × 10⁻³ | 4.34 × 10⁻⁵ |
| 11 | | 1.00 × 10⁻³ | | 126 | 176 | 3.45 × 10⁻² | 2.00 × 10⁻³ | 6.90 × 10⁻⁵ |
| 12 | | 1.50 × 10⁻⁴ | | 141 | 93 | 6.21 × 10⁻² | 1.60 × 10⁻³ | 9.94 × 10⁻⁵ |

*Estimated value

As shown in Table 2, a film thickness d₁ was 1 μm. It was possible to form a thin film beyond the expectation by drying/modification. This is considered because it was possible to heat beyond the expectation. Further, as shown in Table 2, it was possible to obtain multiple times a target temperature of 180° C. or less and a target resistivity ρ of 1×10⁻⁵ Ωcm or less order within a short period of time which is 5 minutes (a target period of time is 30 minutes or less). Further, there was a case of obtaining an extremely low resistivity that is 4/3 times as the resistivity of Ag bulk (No. 4: 1.97×10⁶ Ωcm).

(Application to Impurity Activation Annealing)

Next, there will be described an example in which the electromagnetic heating method of the present embodiment is applied to an impurity activation annealing.

Among manufacturing processes of a semiconductor device, there is a process of forming an impurity diffusion layer by injecting impurities to a semiconductor substrate and performing an impurity activation annealing. Recently, along with the miniaturization of a design rule of the semiconductor device, it is required an annealing technique at a low temperature in which thermal diffusion of impurities for extremely thin diffusion layer (ultra shallow junction (USJ)) is suppressed. As a technique for suppressing impurity diffusion, it is also being reviewed a solid phase epitaxy in which an impurity doping region becomes amorphous, the region is doped with impurity, and annealing is performed at a low temperature, thereby performing recrystallization and impurity activation.

The electromagnetic heating has been suggested as a heating method capable of performing annealing at a low temperature. However, conventionally, a way to efficiently heat by using electromagnetic waves has not been established, so that the electromagnetic heating has not yet been practically used.

In the present example, the electromagnetic heating based on the electromagnetic wave absorption design in accordance with the present embodiment is performed in order to activate impurities or to activate impurities and recrystallize after performing impurity doping on the semiconductor substrate.

Specifically, a substrate (Si substrate) having a thickness obtained by the electromagnetic wave absorption design is prepared, and impurity doping is performed on the substrate. Thereafter, annealing is performed to activate impurities or to activate impurities and recrystallize by irradiating electromagnetic waves having a frequency that satisfies the non-reflection condition. By doing so, the substrate is modified to obtain desired semiconductor characteristics. At this time, in order to make the substrate have preferable characteristics after the irradiation of the electromagnetic wave, substrate quality, temperature, electromagnetic wave irradiation condition (power and time) and the like are optimized and then the electromagnetic heating is performed.

At the time of impurity activation or impurity activation and recrystallization, the electromagnetic heating using the electromagnetic wave absorption design in accordance with the present embodiment is performed, so that electromagnetic waves are efficiently absorbed to the substrate, thereby obtaining desired semiconductor characteristics.

Next, a test example of a case where a Si substrate doped with impurities is used as a target object to be heated will be described.

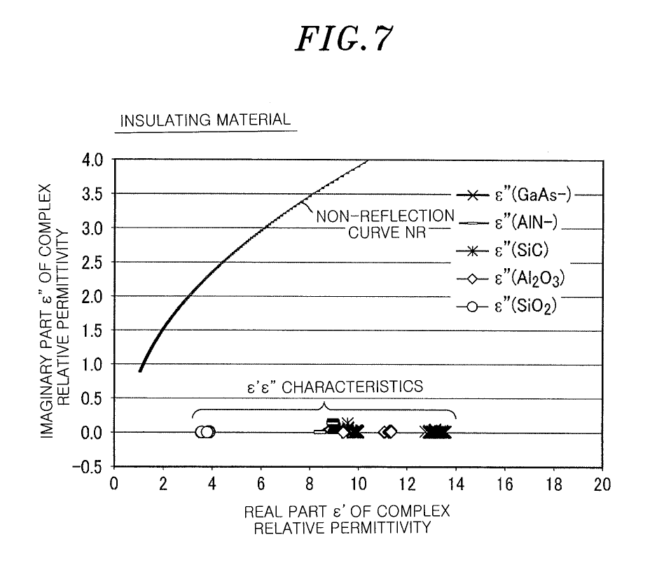

FIG. 6A illustrates, when a frequency of the electromagnetic wave irradiated to the Si substrate (Si⁺) doped with impurities varies between 100 kHz and 100 GHz, ∈′∈″ characteristics indicating the change of the complex relative permittivity and non-reflection curve. FIG. 6B is an enlarged view of a part of FIG. 6A. As shown in FIGS. 6A and 6B, there is an intersection point between the ∈′∈″ characteristics (experimental value) and the non-reflection curve (theoretical value). By reading the intersection point, a frequency of the electromagnetic wave and a thickness of the target object can be derived. Contrarily, as shown in FIG. 7, no intersection point exists with respect to the other insulating materials than SiO₂, so that it has been found that there is a possibility of being able to selectively heat the Si substrate even in a case where the other materials coexist therewith.

Based on the values read from FIGS. 6A and 6B, the electromagnetic wave absorption design was performed with respect to the Si substrate doped with impurities. The results are shown in the following Table 3.

TABLE 3

| | From complex relative | | | | | | | |
|---|---|---|---|---|---|---|---|---|
| | permittivity | | | From non-reflection curve | | | | |
| | (Experiment) | | | (Theory) | | | | Intersection |
| Material | ε′ | ε″ | f | ε′ | ε″ | d/λ | d (m) | point |
| Si⁺ | 10.3 | 4.0 | 5.6 GHz | 13.2 | 4.52 | 0.07 | 3.8 × 10⁻³ | ? |
| | 11.4 | 7.4 | 30 GHz | ″ | ″ | 0.07 | 7.0 × 10⁻⁴ | exist |
| | 11.3 | 5.6 | 40 GHz | ″ | ″ | 0.07 | 5.3 × 10⁻⁴ | exist |
| | 11.4 | 4.4 | 50 GHz | ″ | ″ | 0.07 | 4.2 × 10⁻⁴ | exist |
| | 11.2 | 2.1 | 100 GHz | ″ | ″ | 0.07 | 2.1 × 10⁻⁴ | exist |

From Table 3, it is seen that, under a frequency of 30 GHz of the irradiated electromagnetic wave, a thickness of 700 μm becomes one of the design values of the non-reflection condition.

In this example, the ∈′∈″ characteristics and the non-reflection curve are not one line on a macro scale, and therefore, as the intersection point, plural values exist and these plural values are shown in Table 3.

Referring to the above electromagnetic wave absorption design as a guideline, a test was performed with the electromagnetic wave of 28 GHz frequency. Here, TEGs (test element groups) having specifications of Nos. 1 to 3 shown in Table 4 was used. Electromagnetic waves were irradiated under conditions shown in Table 4 to perform impurity diffusion or impurity diffusion and recrystallization, and then sheet resistance was measured.

TABLE 4

| | | | Handy low resistivity | | | |
|---|---|---|---|---|---|---|
| | | | meter | | Sheet | |
| | | | Rs (Ω/□) | Rs (Ω/□) | resistor | |
| | Rs-TEG | Irradiation | small | large | VR-120 | Surface |
| No. | specification | condition | probe | probe | Rs (Ω/□) | observation |
| 1 | (Ge 30 keV | initial | Immeasurable | Immeasurable | Immeasurable | |
| | 5 × 10¹⁴) | 28 GHz | 141 | 136 | 144 | |
| | (B 5 keV | after 5 min | | | | |
| | 3 × 10¹⁵) | 28 GHz | 180 | 139 | 148 | |
| | | after 30 min | | | | |
| 2 | (As 50 keV | initial | Immeasurable | Immeasurable | Immeasurable | |
| | 1 × 10¹⁵) | 28 GHz | 157 | 150 | 211 | Color |
| | | after 5 min | | | | shading |
| | | | | | | exists in |
| | | | | | | surface |
| | | 28 GHz | 154 | 322 | 147 | |
| | | after 30 min | | | | |
| 3 | (P 2 keV | initial | Immeasurable | Immeasurable | Immeasurable | |
| | 1 × 10¹⁵) | 28 GHz | 591 | 481 | 684 | |
| | | after 5 min | | | | |
| | | 28 GHz | 346 | 503 | 682 | |
| | | after 30 min | | | | |

The sheet resistance was infinity (immeasurable) before the irradiation of the electromagnetic waves. After the irradiation of the electromagnetic waves, the sheet resistance was changed to 144 to 684Ω (Ω/□) and activation was found in all of the TEGs.

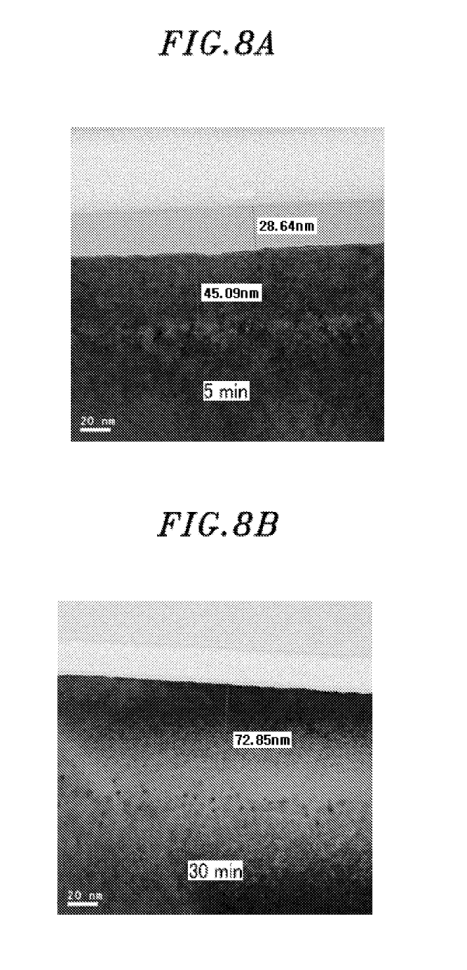

As to the TEG of No. 1 shown in Table 4, FIG. 8A shows a picture of a cross section taken by a transmission electron microscope (TEM) after the irradiation for 5 minutes, and FIG. 8B shows a TEM picture of a cross section after the irradiation for 30 minutes. It is confirmed that crystallization and defect recovery are performed by the electromagnetic wave irradiation in accordance with the present embodiment. In addition, it is confirmed that as the irradiation time is longer, the defect recovery is further performed.

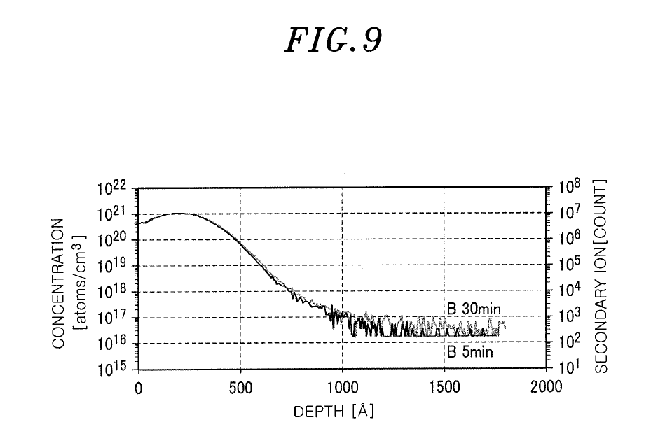

As to the TEG of No. 1, FIG. 9 is a view showing a change in B concentration in a depth direction by a secondary ion mass spectrometry (SIMS) after the activation caused by the electromagnetic wave irradiation. From FIG. 9, it is found that B (boron) hardly diffuses by the activation caused by the electromagnetic wave irradiation.

(Electromagnetic Heating Device)

Next, an electromagnetic heating device that can implement the above electromagnetic heating method will be described.

(First Example of Electromagnetic Heating Device)

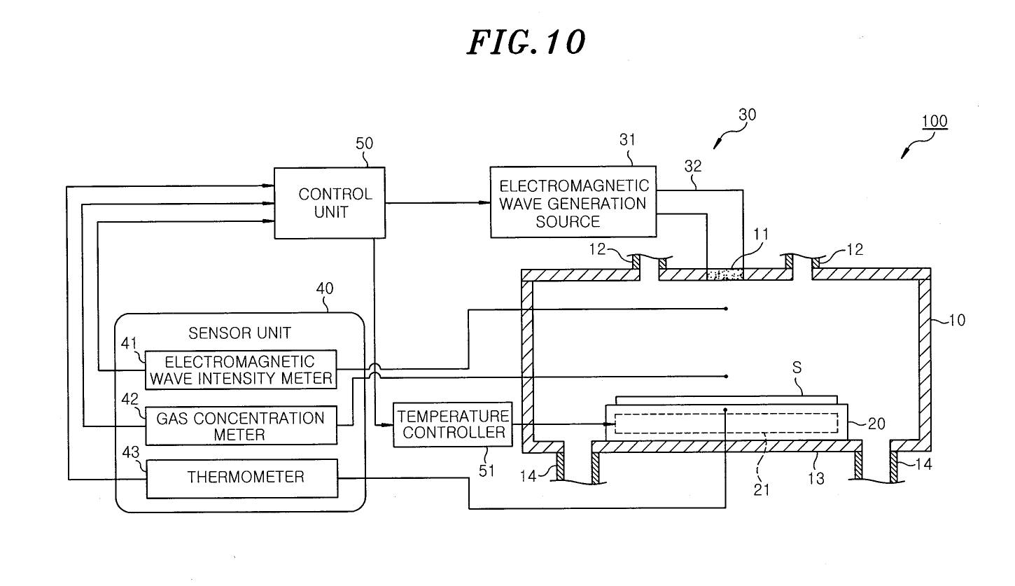

FIG. 10 is a cross-sectional view showing a schematic configuration of the first example of the electromagnetic heating device that can implement the electromagnetic heating method of the present embodiment. The electromagnetic heating device 100 includes a process chamber 10, a mounting table 20, an electromagnetic wave supply unit 30, a sensor unit 40 and a control unit 50.

The process chamber 10 is grounded and the inner sidewalls thereof are formed by, e.g., a mirror-like finishing by using aluminum. In the center of the ceiling wall of the process chamber 10, a ceiling plate 11 made of a material capable of transmitting electromagnetic waves, e.g., a dielectric such as quartz, aluminium nitride and the like is inserted. A gas introduction unit 12 is provided at the ceiling wall of the process chamber 10 and a predetermined process gas is introduced through the gas introduction unit 12. As the process gas, an inert gas such as argon gas, nitrogen gas and the like may be suitable used. An exhaust port 14 is provided at a bottom wall 13 of the process chamber 10 and the inside of the process chamber 10 is exhausted through the exhaust port 14 by an exhaust mechanism (not shown) to be maintained at a predetermined pressure.

The mounting table 20 is arranged on the bottom of the process chamber 10, and a substrate S is mounted on the mounting table 20. The substrate may be one on which a coating film serving as a target object to be heated is formed, or the substrate itself may be the target object to be heated. A temperature control mechanism 21 for heating and/or cooling the substrate is provided in the mounting table 20.

The electromagnetic wave supply unit 30 is arranged on the ceiling wall of the process chamber 10 and includes an electromagnetic wave generation source 31 and a waveguide 32. The electromagnetic wave supply unit 30 guides electromagnetic waves generated in the electromagnetic wave generation source 31 into the process chamber 10 through the waveguide 32 and the ceiling plate 11 of the process chamber 10. The electromagnetic wave generation source 31 has a variable frequency and the frequency is controlled according to the command from the control unit 50. A RF power source, magnetron, klystron, gyrotron and the like may be used as the electromagnetic wave generation source 31. In a case where a frequency range of the irradiated electromagnetic wave is wide, it is preferable that a plurality of electromagnetic wave generation sources having different frequency ranges is installed as the electromagnetic wave generation source 31 and the electromagnetic wave generation sources are switched depending on the frequency. It is preferable that a variable range of the irradiated electromagnetic wave frequency is a part of a range between 0.1 kHz and 10 THz.

The sensor unit 40 includes an electromagnetic wave intensity meter 41, a gas concentration meter 42 and a thermometer 43. The electromagnetic wave intensity meter 41 measures electromagnetic wave intensity in a space within the process chamber 10. The gas concentration meter 42 measures gas concentration in the process chamber 10. The thermometer 43 measures a temperature of the substrate S on the mounting table 20. The sensor unit 40 may not include all of them.

The control unit 50 includes a microprocessor (computer), and controls the respective components of the electromagnetic heating device 100 in response to a predetermined signal from, e.g., the sensor unit 40. For example, the control unit 50 controls the substrate temperature by sending a command to the temperature control mechanism 21 through a temperature controller 51. The control unit 50 includes a storage unit which stores process recipes that are process sequences and control parameter of the electromagnetic heating device 100, and the like. The control unit 50 further includes an input means, a display, and the like. The control unit 50 is configured to control the respective components of the electromagnetic heating device 100 according to a selected process recipe.

Further, the control unit 50 has control algorithms for implementing the aforementioned electromagnetic heating method of the present embodiment.

With respect to the coating film on a surface of the substrate S or with respect to the substrate S itself serving as a target object to be heated, the control unit 50 draws the ∈′∈″ characteristics of the target object on a complex plane when a frequency of the irradiated electromagnetic wave varies, and also draws the non-reflection curve of the target object on the same complex plane. Then, the control unit 50 determines a frequency of the electromagnetic wave and a thickness of the target object based on a value obtained from an intersection point between the ∈′∈″ characteristics and the non-reflection curve, and controls the electromagnetic heating based on the determined frequency and thickness.

Specifically, in a case where the frequency of the electromagnetic wave can vary while the thickness of the target object is fixed, a wavelength λ is calculated by inserting a value of the thickness d of the target object into the thickness/wavelength ratio (d/λ) derived from the non-reflection curve at the intersection point between the ∈′∈″ characteristics and the non-reflection curve on the complex plane, and an electromagnetic wave frequency f is obtained from the wavelength λ. The electromagnetic heating is performed by controlling a central value of the frequency of the electromagnetic wave generated by the electromagnetic wave generation source 31 to become f. On the other hand, in a case where the thickness of the target object can vary while the frequency of the electromagnetic wave is fixed, a frequency f is obtained from the ∈′∈″ characteristics at the intersection point, and a thickness d of the target object is obtained from the frequency f and the d/λ value derived from the non-reflection curve at the intersection point. The electromagnetic heating is performed by controlling the output of the electromagnetic wave generation source 31 such that the thickness of the target object becomes d.

At this time, data of the ∈′∈″ characteristics and the non-reflection curve drawn on the complex plane with respect to the target object of electromagnetic heating are obtained in advance, and the data may be stored in the control unit 50. From these data, a wavelength λ is calculated by inserting a value of the thickness d of the target object into the thickness/wavelength ratio (d/λ) derived from the non-reflection curve at the intersection point, and an electromagnetic wave frequency f is obtained from the wavelength λ. Otherwise, a frequency f is obtained from the ∈′∈″ characteristics at the intersection point, and a thickness d is obtained from the frequency f and the d/λ value derived from the non-reflection curve at the intersection point.

As such, the frequency of the electromagnetic wave and the thickness of the target object are determined to thereby realize the electromagnetic heating satisfying the electromagnetic wave absorption design.

However, in a real process, there may be a case where the electromagnetic heating is performed optimally at a frequency slightly different from the frequency f satisfying the electromagnetic wave absorption design. In this case, it is preferable that a frequency of the electromagnetic wave is corrected so as to make the predetermined parameter optimal.

Specifically, in this case, the following control is performed by the control unit 50. A frequency of the electromagnetic wave from the electromagnetic wave generation source 31 is corrected to become a frequency at which reflection intensity measured by the electromagnetic wave intensity meter 41 becomes a minimum while changing the frequency of the electromagnetic wave from the frequency f that is a central value. Alternatively, a frequency of the electromagnetic wave from the electromagnetic wave generation source 31 is corrected to become a frequency at which a substrate temperature measured by the thermometer 43 is almost equal to a set substrate temperature value while changing the frequency of the electromagnetic wave from the frequency f that is a central value. Otherwise, a frequency of the electromagnetic wave from the electromagnetic wave generation source 31 is corrected to become a frequency at which a measured concentration value of a predetermined gas, e.g., an ink component included in the coating film detected by the gas concentration meter 42 is almost equal to a set concentration value while changing the frequency of the electromagnetic wave from the frequency f that is a central value.

By doing this, in the entire film forming process, even when thickness difference of the coating film, temperature difference of the substrate, and concentration difference of the coating film (ink) component exist, they can be controlled in a feedback manner, so that process deviation can be suppressed. Accordingly, a short process time and a high process yield are realized to thereby improve overall productivity.

(Second Example of Electromagnetic Heating Device)

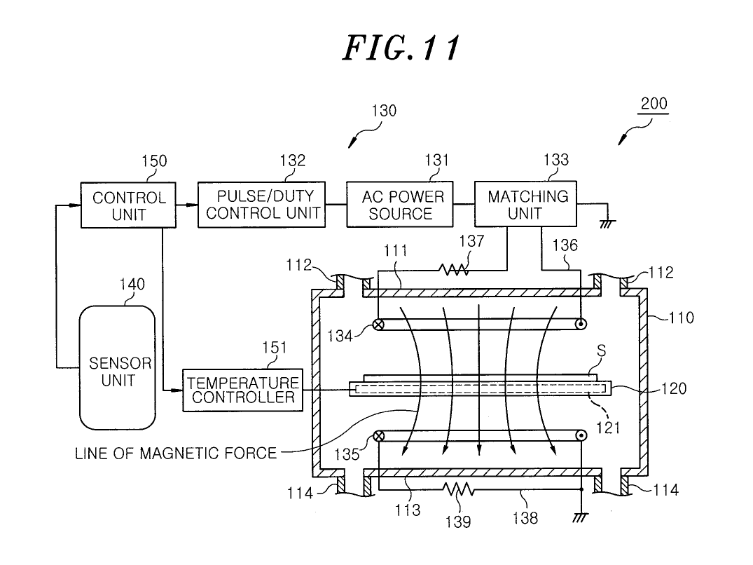

FIG. 11 is a cross-sectional view showing a schematic configuration of the second example of the electromagnetic heating device that can implement the electromagnetic heating method of the present embodiment. The electromagnetic heating device 200 includes a process chamber 110, a mounting table 120, an electromagnetic wave supply unit 130, a sensor unit 140 and a control unit 150.

The process chamber 110 is made of a material having an electromagnetic wave shield function such as stainless steel (SUS), aluminum or the like. A gas introduction unit 112 is provided at the ceiling portion 111 of the process chamber 110 and a predetermined process gas is introduced through the gas introduction unit 112. As the process gas, an inert gas such as argon gas, nitrogen gas or the like may be suitably used. An exhaust port 114 is provided at a bottom wall 113 of the process chamber 110 and the inside of the process chamber 110 is exhausted through the exhaust port 114 by an exhaust mechanism (not shown) to be maintained at a predetermined pressure.

The mounting table 120 is arranged on the bottom portion of the process chamber 110, and a substrate S is mounted on the mounting table 120. The substrate may be one on which a coating film serving as a target object to be heated is formed, or the substrate itself may be the target object to be heated. A temperature control mechanism 121 for heating and/or cooling the substrate is provided in the mounting table 120. The mounting table 120 may be configured as a cooling plate made of non-doped silicon, aluminium nitride (AlN), silicon carbide (SiC), alumina (Al₂O₃) or the like.

The electromagnetic wave supply unit 130 includes an alternating current (AC) power source 131, a pulse/duty control unit 132, a matching unit 133, a transmission antenna 134, and a reception antenna 135. The transmission antenna 134 has a ring shpe, and is arranged at an upper portion in the process chamber 110 to face the mounting table 120. An AC having a frequency of, e.g., about 100 Hz to 50 kHz is supplied from the AC power source 131 to the transmission antenna 134 through the matching unit 133. The AC power source 131 has a variable frequency, which is controlled according to the command from the control unit 150. A matching load 137 is connected to a power supply line 136 through which power is supplied to the transmission antenna 134. The pulse/duty control unit 132 is configured to change the AC outputted from the AC power source 131 to a pulse having a predetermined duty ratio. The reception antenna 135 has a ring shape and is arranged, below the mounting table 120, at a position corresponding to the transmission antenna 134. A ground line 138 is connected to the reception antenna 135, and a matching load 139 is connected to the ground line 138.

The sensor unit 140 and the control unit 150 have the same configuration as the sensor unit 40 and the control unit 50 of the first example, respectively. That is, the sensor unit 140 includes an electromagnetic wave intensity meter, a gas concentration meter and a thermometer. However, the sensor unit 140 may not necessarily include all of them. The control unit 150 controls the respective components of the electromagnetic heating device 200 and has control algorithms for implementing the aforementioned electromagnetic heating method of the present embodiment. For example, the control unit 150 controls a substrate temperature by sending a command to the temperature control mechanism 121 through a temperature controller 151.

In the electromagnetic heating device 200, in a state where the substrate S is mounted on the mounting table 120, an AC having a frequency of, e.g., about 100 Hz to 50 kHz is supplied from the AC power source 131 to the transmission antenna 134 through the matching unit 133. Then, a magnetic field passing through the transmission antenna 134 and the reception antenna 135 is generated, and due to electromagnetic induction, electromagnetic wave having a frequency of the AC power source 131 is irradiated to the substrate S. At this time, the AC outputted from the AC power source 131 may be changed to a pulse having a predetermined duty ratio by the pulse/duty control unit 132 to control the substrate S to be cooled.

As in the first example, also in the present example, the control unit 150 determines a frequency of the electromagnetic wave and a thickness of the target object based on a value obtained from an intersection point between the ∈′∈″ characteristics and the non-reflection curve, and controls the electromagnetic heating based on the determined frequency and thickness. Accordingly, the electromagnetic heating satisfying the electromagnetic wave absorption design can be realized by determining the frequency of the electromagnetic wave and the thickness of the target object. Further, as in the first example, a frequency of the electromagnetic wave may be corrected so as to make the predetermined parameter optimal.

The reception antenna 135 is not essential. Even when the reception antenna 135 is not provided, a magnetic field is generated from the transmission antenna 134 so that electromagnetic wave can be irradiated to the substrate S.

(Third Example of Electromagnetic Heating Device)

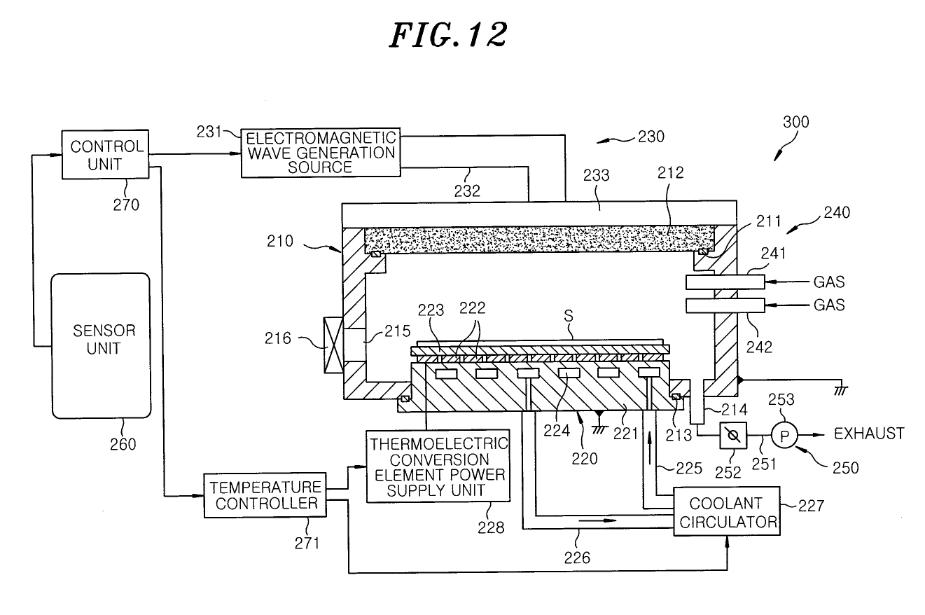

FIG. 12 is a cross-sectional view showing a schematic configuration of the third example of the electromagnetic heating device that can implement the electromagnetic heating method of the present embodiment. FIG. 12 shows more specifically the electromagnetic heating device 300 which performs the electromagnetic heating based on the same fundamentals as in FIG. 10. The electromagnetic heating device 300 includes a process chamber 210, a mounting table 220, an electromagnetic wave supply unit 230, a gase introduction mechanism 240, an exhaust mechanism 250, a sensor unit 260 and a control unit 270.

The process chamber 210 is made of, e.g., stainless steel, aluminum, aluminum alloy or the like, and is grounded. The ceiling portion of the process chamber 210 is opened, and a ceiling plate 212 is airtightly provided at this opened portion through a sealing member 211. The ceiling plate 212 is made of a material through which electromagnetic wave is transmitted, e.g., a dielectric such as quartz, aluminium nitride or the like. An exhaust port 214 connected to the exhaust mechanism 250 is provided at the periphery of the bottom of the process chamber 210. A loading/unloading port 215 through which the substrate S is loaded/unloaded is formed at the side wall of the process chamber 210. The loading/unloading port 215 can be opened or closed by a gate valve 216.

The mounting table 220 is airtightly attached to an opening formed at the bottom of the process chamber 210 through a sealing member 213. The mounting table 220 is grounded. The mounting table 220 includes a table main body 221, thermoelectric conversion elements 222 and a mounting plate 223. The thermoelectric conversion elements 222 are disposed on the table main body 221, and the mounting plate 223 is disposed on the thermoelectric conversion elements 222. The substrate S is mounted on the mounting plate 223. The thermoelectric conversion elements 222 are supplied with power from a thermoelectric conversion element power supply unit 228 to heat the substrate S. A coolant path 224 is formed in the table main body 221. The coolant path 224 is connected to a coolant circulator 227 for circulating a coolant through a coolant inlet line 225 and a coolant outlet line 226. The coolant is circulated through the coolant path 224 by the coolant circulator 227, so that the plastic substrate S can be cooled.

The electromagnetic wave supply unit 230 is arranged on the ceiling plate 212 of the process chamber 210. The electromagnetic wave supply unit 230 includes an electromagnetic wave generation source 231, a waveguide 232 and an incident antenna 233. The electromagnetic wave generation source 231 is connected to one end of the waveguide 232, and the other end of the waveguide 232 is connected to the incident antenna 233. The electromagnetic wave generation source 231 has a variable frequency, which is controlled by a command from the control unit 270. A RF power source, magnetron, klystron, gyrotron or the like may be used as the electromagnetic wave generation source 231. In a case where a frequency range of the irradiated electromagnetic wave is wide, it is preferable that a plurality of electromagnetic wave generation sources having different frequency ranges is installed as the electromagnetic wave generation source 31 and the electromagnetic wave generation sources are switched depending on the frequency.

The gas introduction mechanism 240 includes, e.g., two gas nozzles 241 and 242 which penetrate through the sidewall of the process chamber 210. The gas introduction mechanism 240 supplies a gas required for a process from a gas supply source (not shown) into the process chamber 210. Here, the required gas is an inert gas including argon, nitrogen or the like. The number of the nozzles is not limited to two but may be properly increased or decreased.

The exhaust mechanism 250 includes an exhaust path 251 through which an exhaust gas passes, a pressure control valve 252 for controlling an exhaust pressure, an exhaust pump 253 for discharging the atmosphere in the process chamber 210. The exhaust pump 253 exhausts the atmosphere in the process chamber 210 to a predetermined vacuum level through the exhaust path 251 and the pressure control valve 252. Alternatively, the atmosphere in the process chamber 210 may not be exhausted and may be set to an atmospheric pressure.

The sensor unit 260 and the control unit 270 are configured same as the sensor unit 40 and the control unit 50 of the first example, respectively. That is, the sensor unit 260 includes an electromagnetic wave intensity meter, a gas concentration meter and a thermometer. However, the sensor unit 260 may not necessarily include all of them. The control unit 270 controls the respective components of the electromagnetic heating device 300 and has control algorithms for implementing the aforementioned electromagnetic heating method of the present embodiment. For example, the control unit 270 controls a substrate temperature by sending a command to the thermoelectric conversion element power supply unit 228 and the coolant circulator 227 through a temperature controller 271.

In the electromagnetic heating device 300 having such configuration, in a state where the substrate S is mounted on the mounting table 220, electromagnetic wave is supplied from the electromagnetic wave supply unit 230 into the process chamber 210, so that the substrate S that is the target object is heated by the electromagnetic wave.

Also in the present example, similar to the first example, the control unit 270 determines a frequency of the electromagnetic wave and a thickness of the target object based on a value obtained from an intersection point between the ∈′∈″ characteristics and the non-reflection curve, and controls the electromagnetic heating based on the determined frequency and thickness. Accordingly, the electromagnetic heating satisfying the electromagnetic wave absorption design can be realized by determining the frequency of the electromagnetic wave and the thickness of the target object. Further, as in the first example, a frequency of the electromagnetic wave may be corrected so as to make the predetermined parameter optimal.

(Fourth Example of Electromagnetic Heating Device)

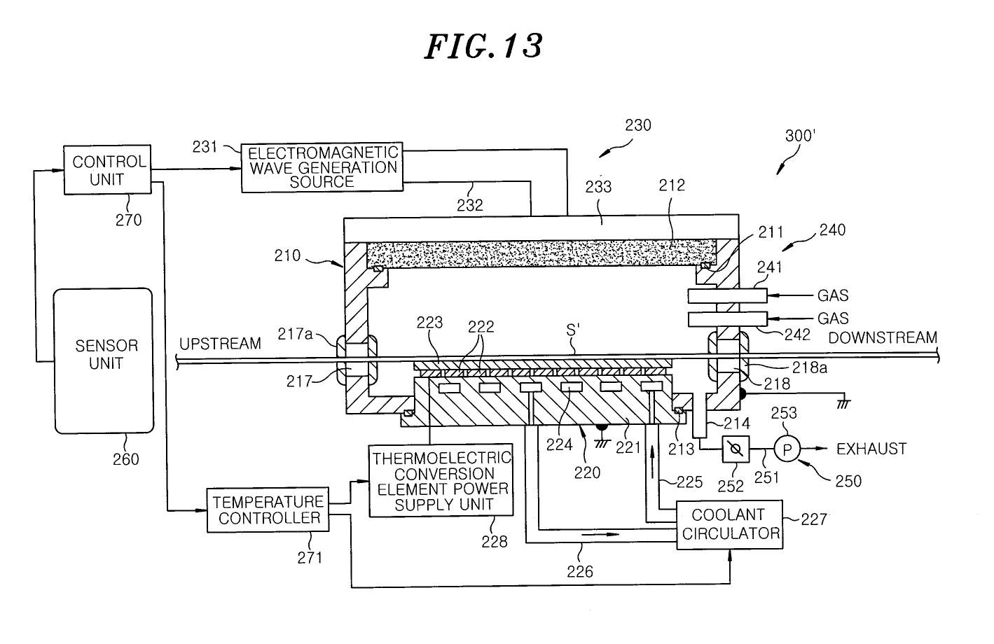

FIG. 13 is a cross-sectional view showing a schematic configuration of the fourth example of the electromagnetic heating device that can implement the electromagnetic heating method of the present embodiment. An electromagnetic heating device 300′ has almost the same configuration as the third example shown in FIG. 12. However, the electromagnetic heating device 300′ is different from the electromagnetic heating device 300 in that the target object to be heated is a sheet-shaped substrate S′ wound around a roll. Accordingly, in FIG. 13, like parts are represented by like reference numerals as those in FIG. 12, and the description thereof will be omitted.

In the present example, the substrate S′ that is the target object is made by, e.g., forming a coating film (e.g., wiring patterns) on a plastic sheet. In this case, an actual heating target is the coating film.

At the sidewall of the process chamber 210, a loading port 217 through which the substrate S′ is loaded before the irradiation of the electromagnetic wave, and an unloading port 218 through which the substrate S′ is unloaded after the irradiation of the electromagnetic wave are provided opposite to each other. Shutters 217a and 218a are provided at the loading port 217 and the unloading port 218, respectively. When a transfer mechanism (not shown) halts the transfer of the substrate S′ and the electromagnetic wave is irradiated, in order to prevent the electromagnetic wave and gas in the process chamber 210 from leaking to the outside, the shutters 217a and 218a close the loading port 217 and the unloading port 218, respectively. The shutters 217a and 218a are made of soft metal, e.g., indium, copper or the like. The shutters 217a and 218a come in contact with the substrate S′ with pressure when the substrate S′ stops. The substrate S′ is wound around a feeding roll (not shown). The substrate S′ is loaded by the inserting roll into the process chamber 210 and is wound around a winding roll (not shown) arranged at the opposite side.

In the present example, the substrate S′ is loaded by the inserting roll (not shown) through the loading port 217 and a predetermined portion of the substrate S′ is mounted on the mounting table 220. When a vacuum atmosphere is formed in the process chamber 210, the loading port 217 and the unloading port 218 are closed by the shutters 217a and 218a. The electromagnetic heating is performed in this state. A lead member on which a coating film is not formed is connected to an end portion of the substrate S′, and the lead member is made to be attached to the winding roll (not shown). By this state, the irradiation of electromagnetic wave to an initial part of the substrate S′ becomes possible. When the electromagnetic heating of a predetermined part of the substrate S′ is completed, the substrate S′ is wound around the winding roll by a predetermined length and a next part of the substrate S′ is subjected to the electromagnetic heating.

Also in the present example, the control unit 270 determines a frequency of the electromagnetic wave and a thickness of the target object based on a value obtained from an intersection point between the ∈′∈″ characteristics and the non-reflection curve, and controls the electromagnetic heating based on the determined frequency and thickness. Accordingly, the electromagnetic heating satisfying the electromagnetic wave absorption design can be realized by determining the frequency of the electromagnetic wave and the thickness of the target object. Further, as in the first example, a frequency of the electromagnetic wave may be corrected so as to make the predetermined parameter optimal.

(Fifth Example of Electromagnetic Heating Device)

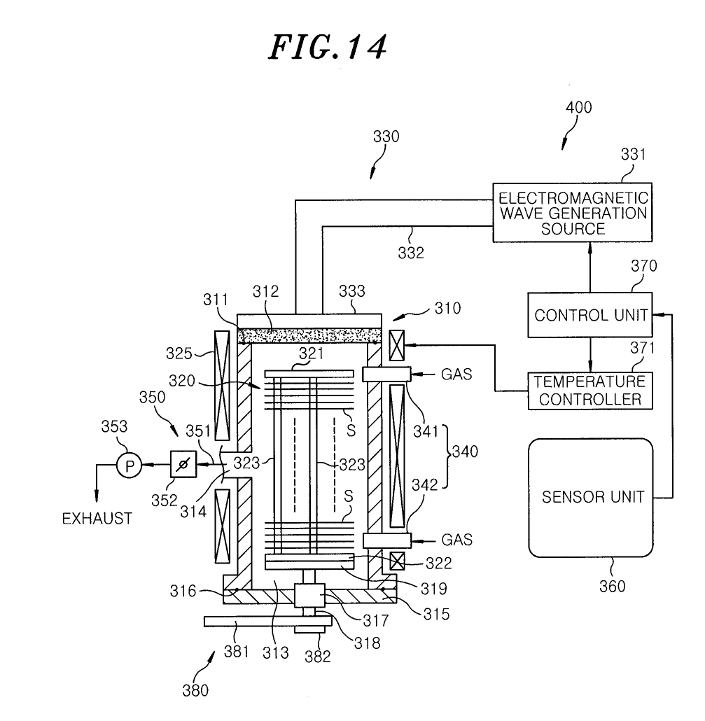

FIG. 14 is a cross-sectional view showing a schematic configuration of the fifth example of the electromagnetic heating device that can implement the electromagnetic heating method of the present embodiment. An electromagnetic heating device 400 is a batch type that can perform the electromagnetic heating with respect to a plurality of substrates S. The electromagnetic heating device 400 includes a process chamber 310, a substrate holding unit 320, an electromagnetic wave supply unit 330, a gas introduction mechanism 340, an exhaust mechanism 350, a sensor unit 360 and a control unit 370.

The process chamber 310 is made of, e.g., stainless steel, aluminum, aluminum alloy or the like, and has a vertically long container shape. The ceiling portion of the process chamber 310 is opened, and a ceiling plate 312 is airtightly provided at the opened portion through a sealing member 311. The bottom portion of the process chamber 310 is also opened and serves as a loading/unloading port 313. An exhaust port 314 is provided at the sidewall of the process chamber 310.

The substrate holding unit 320 vertically holds the substrates S in a horizontal state with a predetermined gap therebetween. The substrate holding unit 320 is detachably provided in the process chamber 310. The substrate holding unit 320 is made of a material through which electromagnetic wave is transmitted, e.g., quartz. Specifically, the substrate holding unit 320 includes a ceiling plate 321 and a bottom plate 322, both made of quartz, which are arranged at the upper and lower sides, respectively. Between the ceiling plate 321 and the bottom plate 322, e.g., four pillars 323 (only two pillars are shown) made of quartz are arranged. Engaging grooves are formed in a step shape in each of the pillars 323 at a predetermined pitch, and the peripheral portions of the substrates are inserted into the respective engaging grooves, so that the substrates S are held at the predetermined pitch. In this case, in order to access the substrate S in a horizontal direction with respect to the substrate holding unit 320 by using a transfer arm (not shown), the four pillars 323 are disposed at a predetermined interval in a region corresponding to a substantially semicircular arc of the substrate S.

An opening/closing cover 315 made of the same metal as the process chamber 310 is detachably attached through a sealing member 316 such as O ring or the like to the loading/unloading port 313 disposed at the lower portion of the process chamber 310. A rotation shaft 318 is provided to airtightly penetrate through the center portion of the opening/closing cover 315 through a magnetic fluid seal 317 provided at the center portion of the opening/closing cover 315. A mounting table 319 is provided on the upper end of the rotation shaft 318. The substrate holding unit 320 is maintained in the process chamber 310 in a state of being mounted on the top surface of the mounting table 319.

Below the process chamber 310, a loading/unloading mechanism 380 for loading/unloading the substrate holding unit 320 into/from the process chamber 310 is provided. The loading/unloading mechanism 380 has a lifting arm 381 that rotatably supports the lower end of the rotation shaft 318, and an elevator (not shown) for elevating the lifting arm 381. A motor 382 for rotating the rotation shaft 318 is installed at the lifting arm 381. The mounting table 319 and the substrate holding unit 320 are rotated by the motor 382.

By moving up and down the lifting arm 381 by driving the elevator, the opening/closing cover 315 and the substrate holding unit 320 integrally move in a vertical direction, and a plurality of substrates S can be loaded and unloaded into and from the process chamber 310. The electromagnetic heating may be performed onto the substrates S without rotating the substrate holding unit 320, and in this case, it is not necessary to provide the motor 382 and the magnetic fluid seal 317.

At the periphery of the process chamber 310, a temperature control mechanism 325 is provided to control a substrate temperature by heating or cooling the substrate S held by the substrate holding unit 320 in the process chamber 310.

The electromagnetic wave supply unit 330 is arranged above the ceiling plate 312 of the process chamber 310. The electromagnetic wave supply unit 330 includes an electromagnetic wave generation source 331, a waveguide 332 and an incident antenna 333. The electromagnetic wave generation source 331 is connected to one end of the waveguide 332, and the other end of the waveguide 332 is connected to the incident antenna 333. The electromagnetic wave generation source 331 has a variable frequency, which is controlled by a command from the control unit 370. A RF power source, magnetron, klystron, gyrotron or the like may be used as the electromagnetic wave generation source 331. In a case where a frequency range of the irradiated electromagnetic wave is wide, it is preferable that a plurality of electromagnetic wave generation sources having different frequency ranges is installed as the electromagnetic wave generation source 31 and the electromagnetic wave generation sources are switched depending on the frequency.

The gas introduction mechanism 340 includes, e.g., two gas nozzles 341 and 342 which penetrate through the sidewall of the process chamber 310. The gas introduction mechanism 340 supplies a gas required for a process from a gas supply source (not shown) into the process chamber 310. Here, the required gas is an inert gas includes argon, nitrogen or the like. The number of the gas nozzles is not limited to two but may be properly increased or decreased.

The exhaust mechanism 350 includes an exhaust path 351 through which an exhaust gas flows, a pressure control valve 352 for controlling an exhaust pressure, and an exhaust pump 353 for discharging the atmosphere in the process chamber 310. The exhaust pump 353 exhausts the atmosphere in the process chamber 310 to a predetermined vacuum level through the exhaust path 351 and the pressure control valve 352. Alternatively, the atmosphere in the process chamber 310 may not be exhausted and may be set to an atmospheric pressure.

The sensor unit 360 and the control unit 370 are configured the same as the sensor unit 40 and the control unit 50 of the first example, respectively. That is, the sensor unit 360 includes an electromagnetic wave intensity meter, a gas concentration meter and a thermometer. However, the sensor unit 360 may not necessarily include all of them. The control unit 370 controls the respective components of the electromagnetic heating device 400 and has control algorithms for implementing the aforementioned electromagnetic heating method of the present embodiment. For example, the control unit 370 controls a substrate temperature by sending a command to the temperature control mechanism 325 through a temperature controller 371.

In the electromagnetic heating device 400 having such configuration, in a state where the substrates S are held by the substrate holding unit 320, electromagnetic wave is supplied from the electromagnetic wave supply unit 330 into the process chamber 310, so that the substrate S that is the target object is heated by the electromagnetic wave. In the present example, the substrates S can be heated all at once by the electromagnetic wave, so that efficient electromagnetic heating can be performed.

As in the first example, also in the present example, the control unit 150 determines a frequency of the electromagnetic wave and a thickness of the target object based on a value obtained from an intersection point between the ∈′∈″ characteristics and the non-reflection curve, and controls the electromagnetic heating based on the determined frequency and thickness. Accordingly, the electromagnetic heating satisfying the electromagnetic wave absorption design can be realized by determining the frequency of the electromagnetic wave and the thickness of the target object. Further, as in the first example, a frequency of the electromagnetic wave may be corrected so as to make the predetermined parameter optimal.

In the fifth example, a vertical type device in which the substrates S in horizontal states are arranged in a vertical direction was used. However, a horizontal type device in which the substrates S in vertical states are arranged in a horizontal direction may be used.

(Other Applications)

The present invention may be variously modified without being limited to the above embodiment. For example, the application in the above embodiment is merely simple example, and the present invention is applicable to the entire cases of heating an object by irradiating electromagnetic wave.

Further, although several examples of the electromagnetic heating device have been described, they are merely simple examples and it is needless to say that the configuration of the device is not limited to the above examples as long as it can implement the electromagnetic heating method of the present invention.

### DESCRIPTION OF REFERENCE NUMERALS

1: electromagnetic wave absorber
2: metal plate
3: electromagnetic wave (plane wave)
100, 200, 300, 300′, 400: electromagnetic heating device
10, 110, 210, 310: process chamber
20, 120, 220: mounting table
30, 130, 230, 330: electromagnetic wave supply unit
40, 140, 260, 360: sensor unit
50, 150, 270, 370: control unit
320: substrate holding unit
S, S′: substrate

What is claimed is:

1. An electromagnetic heating device for heating a target object by irradiating electromagnetic wave, the electromagnetic heating device comprising:
a chamber configured to accommodate the target object;
an electromagnetic wave irradiation unit configured to irradiate the electromagnetic wave to the target object in the chamber, wherein an oscillation frequency of the irradiated electromagnetic wave is variable; and
a control unit configured to control heating by the electromagnetic wave,
wherein the control unit draws, on a complex plane, complex relative permittivity characteristics indicating change in a complex relative permittivity of the target object when a frequency of the irradiated electromagnetic wave varies, also draws a non-reflection curve on the complex plane, determines a frequency of the electromagnetic wave and a thickness of the target object based on a value derived from an intersection point between the complex relative permittivity characteristics and the non-reflection curve, and performs electromagnetic heating based on the determined frequency and thickness.

2. The electromagnetic heating device of claim 1, wherein the control unit calculates a wavelength λ by inserting a value of the thickness d of the target object into a thickness/wavelength ratio (d/λ) derived from the non-reflection curve at the intersection point, and obtains a frequency f of the electromagnetic wave from the wavelength λ.

3. The electromagnetic heating device of claim 1, wherein the control unit obtains a frequency from the complex relative permittivity characteristics at the intersection point and obtains a thickness of the target object from the obtained frequency and a thickness/wavelength ratio (d/λ) derived from the non-reflection curve at the intersection point.

4. The electromagnetic heating device of claim 2, wherein the control unit previously stores data of the complex relative permittivity characteristics indicating a change in the complex relative permittivity of the target object drawn on the complex plane when the frequency of the irradiated electromagnetic wave varies, and data of the non-reflection curve drawn on the complex plane.

5. The electromagnetic heating device of claim 2, further comprising:
an electromagnetic wave intensity meter configured to measure intensity of the electromagnetic wave irradiated from the electromagnetic wave irradiation unit,
wherein the control unit sets a central value of the obtained frequency to the frequency f, and corrects a frequency of the electromagnetic wave irradiated from the electromagnetic wave irradiation unit to become a frequency at which reflection intensity measured by the electromagnetic wave intensity meter becomes a minimum while changing the frequency of the electromagnetic wave from the frequency f that is the central value.

6. The electromagnetic heating device of claim 2, further comprising:
a thermometer configured to measure a temperature of the target object,
wherein the control unit sets a central value of the obtained frequency to the frequency f, and corrects a frequency of the electromagnetic wave irradiated from the electromagnetic wave irradiation unit to become a frequency at which a measuring temperature value of the target object by the thermometer is equal to a setting temperature value while changing the frequency of the electromagnetic wave from the frequency f that is the central value.

7. The electromagnetic heating device of claim 2, further comprising:
a gas concentration meter configured to measure gas concentration of a predetermined gas in the chamber,
wherein the control unit sets a central value of the obtained frequency to the frequency f, and corrects a frequency of the electromagnetic wave irradiated from the electromagnetic wave irradiation unit to become a frequency at which a measuring value of concentration of a predetermined gas detected by the gas concentration meter is equal to a setting value of the concentration while changing the frequency of the electromagnetic wave from the frequency f that is the central value.

8. The electromagnetic heating device of claim 1, wherein a variable range of the oscillation frequency of the electromagnetic wave irradiation unit is a part of a range between 0.1 kHz and 10 THz.

9. The electromagnetic heating device of claim 1, wherein the electromagnetic heating is used for drying or modification of a coating film formed on a substrate.

10. The electromagnetic heating device of claim 1, wherein the electromagnetic heating is used in annealing for impurity activation or for impurity activation and recrystallization after introducing impurities to a substrate for forming a semiconductor substrate.

11. An electromagnetic heating method for heating a target object by irradiating electromagnetic wave, the electromagnetic heating method comprising:
drawing, on a complex plane, complex relative permittivity characteristics indicating a change in complex relative permittivity of the target object when a frequency of irradiated electromagnetic wave varies;
drawing a non-reflection curve on the complex plane;
determining a frequency of the electromagnetic wave and a thickness of the target object based on a value derived from an intersection point between the complex relative permittivity characteristics and the non-reflection curve; and
performing electromagnetic heating based on the determined frequency and thickness.

12. The electromagnetic heating method of claim 11, wherein a wavelength λ is calculated by inserting a value of the thickness d of the target object into a thickness/wavelength ratio (d/λ) derived from the non-reflection curve at the intersection point, and a frequency f of the electromagnetic wave is obtained from the wavelength λ.

13. The electromagnetic heating method of claim 11, wherein a frequency is obtained from the complex relative permittivity characteristics at the intersection point and a thickness of the target object is obtained from the obtained frequency and a thickness/wavelength ratio (d/λ) derived from the non-reflection curve at the intersection point.

14. The electromagnetic heating method of claim 11, wherein the electromagnetic heating is used for drying or modification of a coating film formed on a substrate.

15. The electromagnetic heating method of claim 11, wherein the electromagnetic heating is used in annealing for impurity activation or for impurity activation and recrystallization after introducing impurities to a substrate for forming a semiconductor substrate.
